(19) United States
(12) Patent Application Publication
(10) Pub. No.: US 2024/0105669 A1
(43) Pub. Date: Mar. 28, 2024

(54) DOCUMENT STRUCTURE FORMATION

(71) Applicant: Infineon Technologies AG, Neubiberg (DE)

(72) Inventors: Jens Pohl, Bernhardswald (DE); Uwe Wagner, Abbach (DE); Kristof Bothe, Regensburg (DE); Andreas Kohl, Barbing (DE)

(21) Appl. No.: 18/471,441

(22) Filed: Sep. 21, 2023

(30) Foreign Application Priority Data
Sep. 22, 2022 (DE) 102022209975.3

(51) Int. Cl. H01L 23/00; H01L 23/13; H01L 23/31; H01L 23/498

(52) U.S. Cl. CPC H01L 24/48; H01L 23/13; H01L 23/3121; H01L 23/49838; H01L 24/05; H01L 24/45; H01L 24/49; H01L 24/85; B42D 25/29; H01L 24/29; H01L 24/32; H01L 24/73; H01L 24/83; H01L 24/93; H01L 2224/05548; H01L 2224/05552; H01L 2224/05584; H01L 2224/05644; H01L 2224/05647; H01L 2224/05655; H01L 2224/05664; H01L 2224/05666; H01L 2224/05684; H01L 2224/2919; H01L 2224/32237; H01L 2224/45012; H01L 2224/45124; H01L 2224/45139; H01L 2224/45144; H01L 2224/45147; H01L 2224/4801; H01L 2224/4805; H01L 2224/48101; H01L 2224/48229; H01L 2224/484; H01L 2224/49111; H01L 2224/49176; H01L 2224/73265; H01L 2224/83192; H01L 2224/83862; H01L 2224/83874; H01L 2224/85947; H01L 2224/92247; H01L 2924/0665

(57) ABSTRACT

A chip assembly having a carrier having a cavity and at least one carrier contact, a chip arranged in the cavity and having at least one chip contact, and a wirebond wire, which electrically conductively connects the at least one chip contact to the at least one carrier contact, wherein the wirebond wire is flat-pressed in at least one subregion.

### TECHNICAL FIELD

The disclosure relates to a chip assembly, a method for forming a chip assembly, a document structure, and a method for forming a document structure.

### BACKGROUND

For various applications, such as (e.g., crypto-) banknotes, documents, etc., it is desirable to embed a chip in layers of paper.

The chip should be able to provide contactless communication, for example in the form of near-field communication (NFC), for example as a passive element, which receives energy provided by means of near-field communication, e.g., from a smartphone, and, depending on the intended use, should be configured to perform application-related functions such as signing transactions (e.g., using elliptic-curve cryptography, e.g., a so-called Elliptic Curve Digital Signature Algorithm (ECDSA)).

However, current chip assemblies are typically too thick or are not sufficiently robust due to their design, causing them to be damaged during the manufacturing process or later usage and to fail electrically.

Assuming a conventional banknote with a thickness between approximately 90 μm and 110 μm, and assuming that two layers of paper, each approximately 35 μm thick, should be available to provide the banknote functionality (e.g., to attach/hold the chip and to make mechanical manipulation more difficult or prevent it), between 20 μm and 40 μm remain for a layer in which the chip with the described functionality is to be accommodated, possibly slightly more, for example, up to approximately 70 μm or at least significantly thinner than 100 μm if a slightly thicker banknote is acceptable.

The chip itself is typically too small to accommodate an NFC-suitable antenna directly on the chip, but it may be necessary to arrange the antenna on a carrier on/in which the chip is arranged and connected to the antenna.

However, standard connection technologies such as wire bonding or a flip-chip connection are not suitable because they would result in excessive thickness of the chip assembly.

Conventional wire bonding, for example, requires a minimum height of the wire arc, which is encapsulated (“globtop”); flip chip is unattractive because it requires connections in a cavity of a carrier, which makes the carrier complex and expensive to manufacture, and solders would need to be able to bridge gaps of approximately 200 μm to 300 μm between adjacent contacts, which is not possible due to the surface tension of the solder when molten (instead, the solder would accumulate on both contacts without bridging the gap).

When using conductive pastes, such as conductive adhesives, these are typically applied, for example, by dispensing in a time/pressure-controlled manner by means of needles or by using inkjet printing or stencil printing. This procedure also results in the chip assembly becoming too thick. This is because the thickness of the paste layer is typically determined by material properties such as thixotropic properties, which cause the connecting material typically to extend to a significant height above the contact surfaces. As a result, chip assemblies manufactured according to the prior art using conductive pastes are too thick for use in banknotes and other (paper) documents.

### SUMMARY

In various exemplary embodiments, a chip assembly is provided in which a connecting structure between a chip and a conductor track (which may comprise an antenna, for example) is designed sufficiently thin or flat that the chip assembly can be used in a banknote or a comparably thin (paper) document.

The connecting structure may be formed in various exemplary embodiments as a wirebond wire that is flat-pressed in at least one subregion. Flat-pressing can be carried out by means of a punch, which can have, for example, a flat-pressing surface.

After being mounted on a chip contact and a carrier contact (e.g., an antenna contact), the wirebond wire can be reshaped to a lower height (or thickness), for example, pressed flat, for example by means of a punch which is designed to carry out cold forming, or, for example, by means of a hot thermode, or with an ultrasonic sonotrode, for example.

After the forming, the wirebond wire may have a planar surface in the at least one flat-pressed subregion.

Furthermore, the wirebond wire can form an electrically conductive contact between a chip contact and the carrier contact, wherein the carrier contact can be electrically conductively connected to a conductor track, for example, an antenna arranged on the carrier. The wirebond wire can be formed in such a way that it extends only slightly beyond the surface of the respective contact (i.e., the chip contact or the carrier contact) in height (e.g., away from the chip or carrier), for example, by a maximum of 10 μm or a maximum of 5 μm.

In a subregion that adjoins the at least one flat-pressed sub-region (e.g., between two flat-pressed subregions), the wirebond wire may be flexible (e.g., able to bend) and may extend, for example, within the cavity, for example such that its outer surface, which is located on the side opposite to the carrier, does not protrude beyond a surface of the exposed subregion or can be brought into such a position without damaging the wirebond wire.

In different exemplary embodiments a chip assembly is provided, comprising a carrier having at least one carrier contact and a cavity, a chip arranged in the cavity and having at least one chip contact and at least one wirebond wire, which electrically conductively connects the at least one chip contact to the at least one carrier contact, wherein the wirebond wire is flat-pressed in at least one subregion.

### BRIEF DESCRIPTION OF THE DRAWINGS

Exemplary embodiments of the disclosure are shown in the drawings and will be explained in more detail in the following.

In the drawings:

FIG. 1A is a schematic representation of a chip for use in a chip assembly according to various exemplary embodiments;

FIG. 1B is a schematic illustration of a carrier having at least one carrier contact for use in a chip assembly according to various exemplary embodiments;

FIGS. 2A to 2E shows an illustration of a method for forming a chip assembly according to various exemplary embodiments;

FIGS. 3A and 3B show schematic detailed views of chip assemblies according to various exemplary embodiments;

FIGS. 4A to 4C shows an illustration of a method for forming a chip assembly according to various exemplary embodiments;

FIG. 5 shows schematic detailed views of chip assemblies according to various exemplary embodiments;

FIG. 6A shows an exploded drawing of a document structure according to various exemplary embodiments;

FIG. 6B shows a schematic illustration of a document structure according to various exemplary embodiments;

FIG. 7 shows a flowchart of a method for forming a chip assembly according to various exemplary embodiments; and

FIG. 8 shows a flowchart of a method for forming a document structure according to various exemplary embodiments.

### DETAILED DESCRIPTION

In the detailed description that follows, reference will be made to the attached drawings, which form part of this description and in which specific embodiments in which the invention may be realized are shown for illustration purposes. In this respect, directional terms such as “at the top”, “at the bottom”, “in front”, “behind”, “frontal”, “rear”, etc. are used with respect to the orientation of the figures being described. Because components of embodiments can be positioned in a number of different orientations, the directional terminology is used for illustration purposes only, and is in no way restrictive. It is understood that other embodiments can be used and structural or logical changes can be made without departing from the scope of protection of the present invention. It goes without saying that the features of the various exemplary embodiments described herein can be combined with one another, unless specifically stated otherwise. The following detailed description is therefore not to be understood in a restrictive sense, and the scope of protection of the present invention is defined by the attached claims.

For the purposes of this description, the terms “connected” and “coupled” are used to describe both a direct and an indirect connection, as well as a direct or indirect coupling. In the figures, identical or similar elements are labeled with identical reference numerals, where this is appropriate.

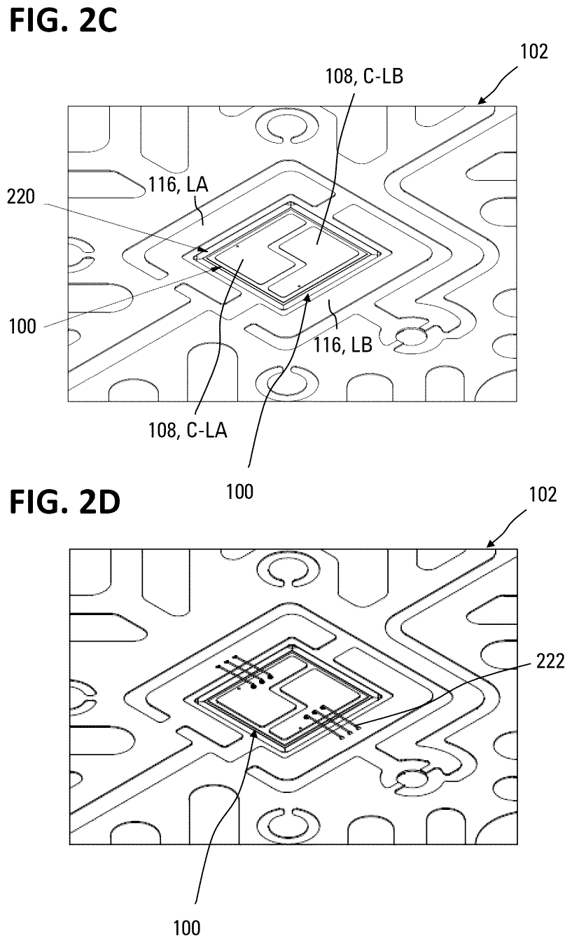

FIG. 2A to 2E illustrates a method for forming a chip assembly 200 according to various embodiments. The method is typically carried out as a roll-to-roll method using a 35 mm band typical of chip-card modules. For the sake of simplicity, only a single module is shown here.

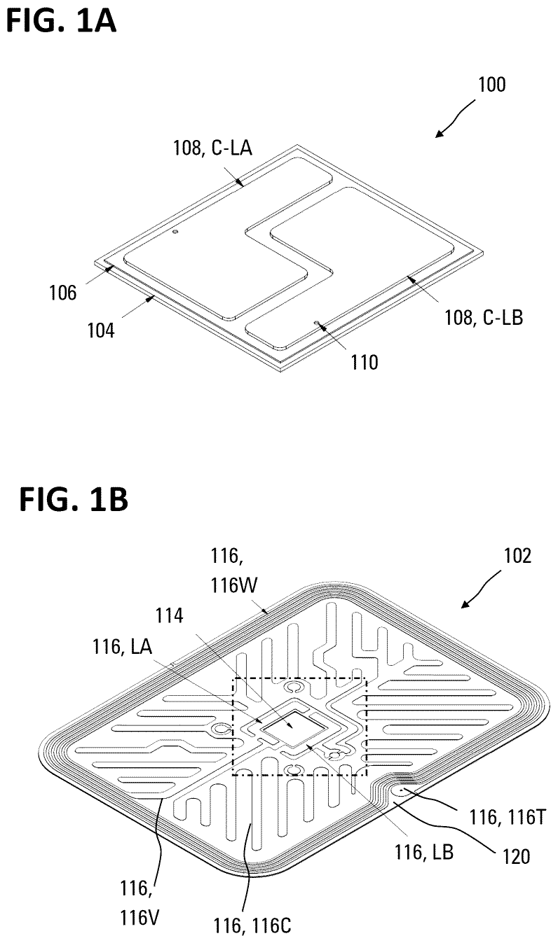

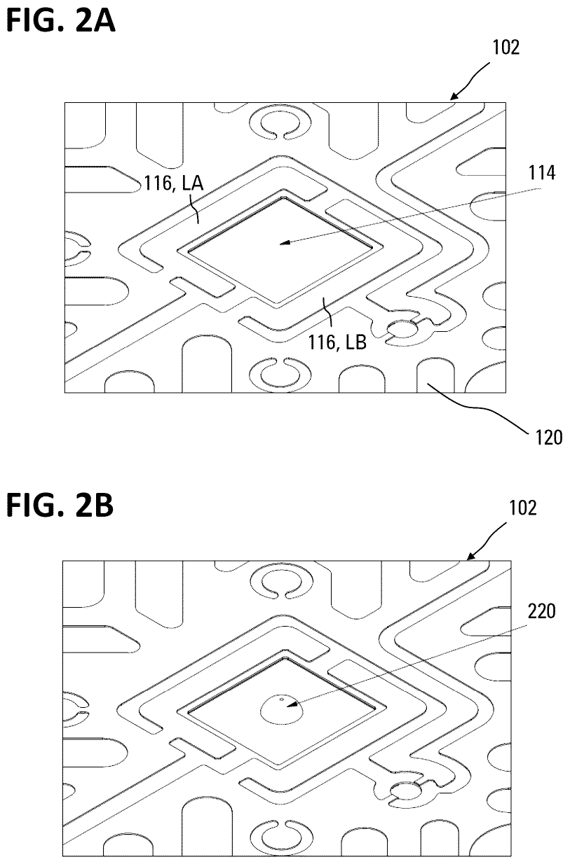

In the method, a chip 100 is inserted into a cavity 114 of a conductor track arrangement 102. In order to prevent the figures used to illustrate the method or properties of the chip assembly 200 according to various embodiments from become too confusing, in FIG. 1A an exemplary chip 100 and in FIG. 1B an exemplary conductor track arrangement 102 (example, an antenna assembly 102), which may be each part of the chip assembly 200 according to various embodiments, are illustrated with extensive reference numerals. In the figures below, reference signs are sometimes omitted. If necessary, FIG. 1A or FIG. 1B can be referred to.

The chip assembly 200 may comprise a carrier 120 having a cavity 114. An example of such a carrier 120 is shown in FIG. 2A.

The carrier 120 can comprise at least one carrier contact LA, LB.

On at least one surface of the carrier 120, a conductor track 116 may be applied. The conductor track 116 may be electrically conductively connected to the at least one carrier contact LA, LB.

For example, the conductor track 116 can form a so-called coil-on-module antenna (CoM antenna) for contactless (CL) communication, and the at least one carrier contact LA, LB can form the two antenna contacts.

The conductor track 116 can be arranged as a structured metallization on the carrier 120. The conductor track 116 in different embodiments can comprise a plurality of functional regions, or at least a few of them, for example antenna windings 116W, connecting structures 116V, capacitive structures 116C and vias 116T. The conductor track (e.g., the antenna) 116 in different embodiments may be formed on both main surfaces of the carrier 120 opposite each other. For example, the antenna windings 116W may be arranged on both main surfaces, and/or the capacitive structures 116C may be arranged on both main surfaces such that together they form a capacitor. A connection between the two main surfaces can be provided by means of the vias 116T. The arrangement of the antenna 116 over both main surfaces of the carrier 120 can be carried out, for example, as in DE 10 2018 105 383 B4.

The conductor track 116 may have a conductor track surface. This is understood to mean an uppermost surface of the conductor track 116, that is, the surface of the conductor track 116 which is farthest away from the carrier 120 and faces away from it. Surfaces of the conductor track 116 that are located between the conductor track surface and the carrier 120 are referred to as side surfaces.

The carrier 120 with the cavity 114 and the conductor track 116 can together form the conductor track arrangement 102.

The chip assembly 200 may comprise a chip 100 arranged in the cavity 114.

The chip 100 may be, for example, a security chip, for example a so-called secure element. The chip 100 may be designed, for example, to sign transactions (e.g., by means of ECDSA), to prove the authenticity of a document in which the chip assembly 200 may be embedded (i.e., to authenticate the document, and/or to store a blockchain or information related to it).

The chip 100 may comprise a very thin semiconductor (e.g., silicon) substrate 104. The thickness of the substrate 104 may, for example, be in a range of approximately 15 μm to approximately 40 μm, for example, from approximately 15 μm to approximately 30 μm.

The chip 100 may have at least one chip contact 108, which can be connected to a circuit of the chip 100 by means of a via (or at least one via per chip contact 108 in the case of a plurality of chip contacts 108).

Between the at least one chip contact 108 and the substrate 104, a passivation layer 106 may be arranged, which may consist, for example, of a polyimide or other common passivation material.

The at least one chip contact 108 may be part of a rewiring layer (RDL), which is applied at wafer level and can serve the purpose of providing chip contacts C-LA, C-LB for the conductor track 116 for contacting the carrier contacts LA, LB.

The rewiring layer—and hence the at least one chip contact 108—typically has a so-called seed layer, which can have, for example, a very thin (compared to the subsequent galvanic layer) Ti or TiW layer with sputtered Cu, and copper galvanically deposited thereon, typically with a thickness in the range of approximately 3 μm to approximately 30 μm, nickel (typically approximately 500 nm to approximately 5 μm) and a topmost thin Au or Pd layer (typically from approximately 50 nm to approximately 150 nm).

In different exemplary embodiments, the at least one chip contact 108 can comprise two chip contacts 108 (C-LA, C-LB), which may be arranged in a polygonal manner, for example L-shaped, and nested. In various exemplary embodiments, an angle between the long leg and the short leg may be 90° or a different angle (larger or smaller). In various embodiments the long legs may be arranged along opposite chip edges, and the short legs may likewise be arranged along opposite chip edges. In other exemplary embodiments, the legs may extend at a different angle (other than parallel) to the chip edge, for example at an angle between 0° and 45°, which may be a consequence of, for example, the crystal structure of the semiconductor material of the substrate 104.

Together, the two chip contacts 108 can cover almost the entire chip surface. As a result, and due to the nested arrangement of the L-shaped contacts, the mechanical stability of the thin chip 100 can be increased, because the thin silicon can then be protected against mechanical stresses along two orthogonal directions.

In order to indicate the connection for which the two chip contacts 108 from the exemplary embodiments are provided, they are additionally labeled in the figures with C-LA (for contact with terminal LA) and C-LB (for contact with terminal LB).

The chip contact 108 can have a chip contact surface. The chip contact surface is to be understood as the top surface of the chip contact 108, that is, the surface which is farthest away from and facing away from a chip substrate 104.

The chip 100 can be, or be arranged in, the cavity 114 such that its at least one chip contact 108 faces away from the cavity 114. In other words, the at least one chip contact 108 is exposed when the chip 100 is arranged in the cavity 114.

To arrange (or fix) the chip 100 in the cavity 114, for example, an adhesive 220, e.g., a non-conductive adhesive (NCA/CNP), can be arranged in the cavity 114, for example by means of a needle dispenser or a jetter nozzle. The adhesive 220 can be epoxy-based, for example. An example of the procedure is shown in FIG. 2B.

In this case, the adhesive 220 can be partially displaced or deformed. The adhesive 220 can be used to secure the chip 100 in the cavity 114. In various exemplary embodiments, the adhesive 220 can be used to encapsulate parts of the chip 100 wetted by it to provide protection against environmental effects, for mechanical protection of the chip 100, and/or for electrical insulation.

The adhesive 220 can be applied as a single point or in a point grid or in a linear form or in a combination thereof.

After the arrangement of the chip 100 in the cavity 114, the adhesive 220 can be cured, for example by means of heating, e.g., using a heating plate, an oven, a thermode, or by light curing (e.g., UV light), or a combination thereof.

An exemplary conductor track arrangement 102 with the chip 100 arranged in the cavity 114 is shown in FIG. 2C. Adhesive 220 displaced from the bottom of the cavity 114 has penetrated into a gap between the side walls of the carrier 120 and the side walls of the chip 100, and partially or completely covers the bottom of the cavity. On an upper side, the adhesive 220 can form a hollow groove in the gap.

The chip assembly 200 may further comprise a wirebond wire 222, which electrically conductively connects the at least one chip contact 108 to the at least one carrier contact LA, LB (and hence also to the conductor track 116, e.g., the antenna).

If more than one chip contact 108 (e.g., C-LA and C-LB) is provided, and more than one carrier contact LA, LB is present (e.g., two antenna contacts), each of the chip contacts C-LA, C-LB can be electrically conductively connected to one of the carrier contacts LA, LB.

The wirebond wire 222 can be a metal wire, commonly used for producing wirebond connections in the chip sector.

Commonly used wires have a round cross-section, but other cross-sections can also be used, e.g., rectangular, as in the case of aluminum ribbon bonding.

For example, the wirebond wire can be a pure gold wire (of the 4N type), which is very soft and is ideally suited for flat-pressing.

Gold alloys or other materials such as copper, aluminum and/or silver, or alloys thereof or of other metals, or multi-layered wires with different metals or metal alloys may be suitable alternatives and used as required or available.

A cross-section of the wirebond wire 222 before flat-pressing may be round or elliptical, for example, or have any other suitable shape.

The wirebond wire 222 can be first attached to the contacts to be connected (the chip contact 108 and the carrier contact LA/LB), for example by means of wire bonding methods known from the prior art, for example, wedge bonding, nailhead bonding, wire-on-bump (WOB) bonding, etc., wherein the contacting on the chip contact 108 can be implemented using the same or a different method as the contacting on the carrier contact LA, LB. In the case of an aluminum wirebond wire, the wedge bonding technique is typically used.

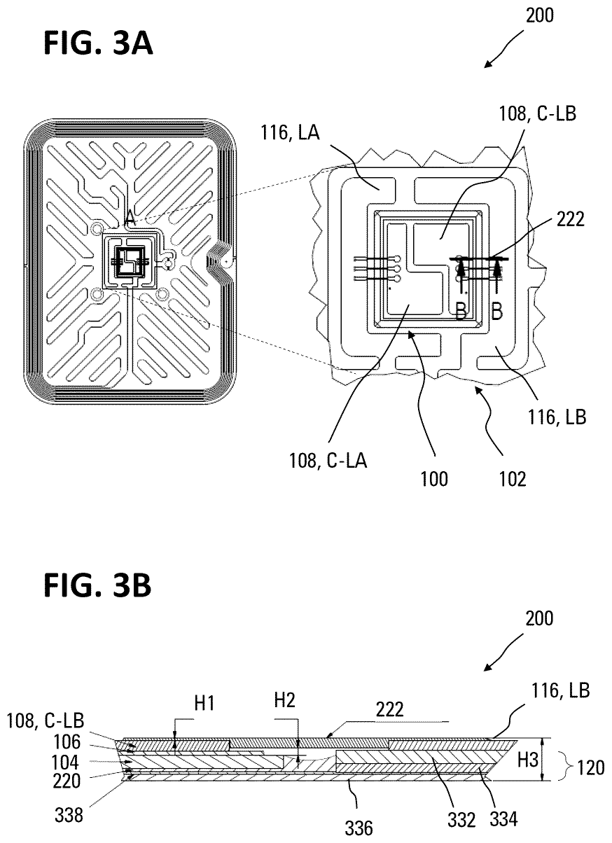

The wirebond wire 222 can be routed along the shortest path between the contacting operations, i.e., in a straight or substantially straight line (an example of this is shown in FIG. 2C and FIG. 4A, for three wirebond wires 222 between the chip contact C-LA and the carrier contact LA, and three further wirebond wires 222 between the chip contact C-LB and the carrier contact LB) or with a surplus length, so that before flat-pressing the wirebond wire 222 can bend into the cavity 114 in a predetermined or arbitrary direction, for example away from the carrier 120, or, for example, substantially parallel to a surface of the chip contact 108 or the carrier contact LA/LB.

Subsequently, at least one subregion 222T1, 222T2 of the wirebond wire 222 can be reshaped (for example, flat-pressed) so that the wirebond wire 222 has a planar surface in the at least one subregion. A surface which is used to exert a force for reshaping the wirebond wire 222 may be planar or substantially planar. This planarity can be transferred to the wirebond wire 222 during the reshaping process.

An example of the result of flat-pressing is shown in FIG. 2E, and an example of the flat-pressing process is illustrated in FIG. 4B.

In different exemplary embodiments, by means of flat-pressing of the at least one subregion of the wirebond wire 222, the thickness H3 of the chip assembly 200 can be minimized.

The wirebond wire 222 can be pressed onto the chip contact during flat-pressing, forming the flat-pressed first subregion 222T1 in the process. Preferably at the same time or optionally subsequently or in advance, the wirebond wire 222 can be pressed onto the carrier contact and form the flat-pressed second subregion 222T2 in the process.

A geometry of the chip assembly 200 and parameters such as pressure (and optionally temperature) and a deformability, such as elasticity, of the wirebond wire 222, which influence the flat-pressing process, can be set in such a way that a specified target thickness can be achieved without damaging the chip or significantly impacting conductivity through the wirebond wire 222.

The target thickness H1 may be less than approximately 10 μm, for example less than approximately 5 μm.

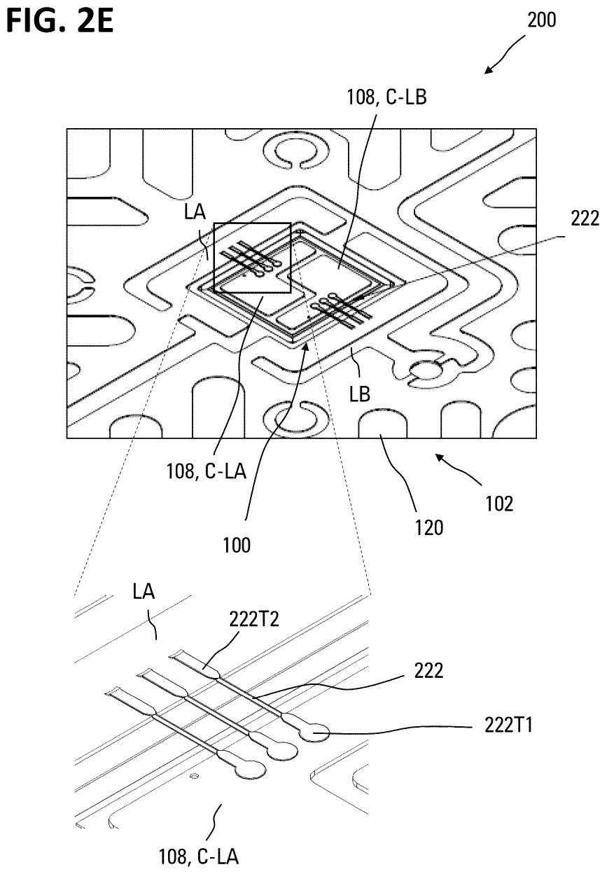

The thickness H3 of the chip assembly 200 can be mainly dependent on the thickness of the chip 100 in various exemplary embodiments, because this thickness is less easily minimized than, for example, the thickness of the carrier 120, which can be formed, for example, as a layer stack (in relation to FIG. 3D it is explained, by way of example, which layers the carrier 120 may have). Accordingly, the thickness of the carrier 120 and of the carrier contact LA, LB (or the conductor track 116, which may optionally be coplanar or integral with the carrier contact LA, LB) can be adjusted in various exemplary embodiments such that the carrier contact surface is coplanar with the chip contact surface, or possibly such that the conductor track surface is the higher surface, in particular to avoid more pressure being applied to the chip 100 than to the conductor track arrangement 102 during the forming process, or to ensure that during flat-pressing, pressure is applied (e.g., by means of the punch or the thermode) mainly to the relatively insensitive conductor track arrangement 102, and not to the more pressure-sensitive chip 100.

Differences in height between a surface of the chip contact 108 and the carrier contact LA, LB can lead to the thickness of the wirebond wire 222 being different in the first subregion 222T1 and in the second subregion 222T2, and also the surface size and shape being different.

In the exemplary embodiment illustrated in FIGS. 3A and 3B surfaces of the chip contact and the carrier contact are coplanar.

In order to achieve good mechanical stability of the flat-pressed wirebond wire connection 222, a shape of the upper edges of the chip contact 108 and the carrier contact LA, LB may be designed accordingly.

This is because a sharp edge, which limits the respective surfaces of the chip contact 108 or the carrier contact LA, LB, could weaken the wirebond wire 222 during the flat-pressing process.

A radius provided for the upper edges of the chip contact 108 or the carrier contact LA, LB can cause the wirebond wire 222 to be reinforced in a transition region near the upper edge of the chip contact 108 or the upper edge of the carrier contact during flat-pressing.

Such a radius at the upper edges of the chip contact 108 or the carrier contact LA, LB can be provided as part of the contact production process, for example as part of the production of the conductor track arrangement 102 or in the chip production.

Typically, during the reshaping step the chip assembly 200 can be arranged such that it rests with a (rear) side facing away from the chip 100 on a planar surface (which may be horizontally aligned, for example). After reshaping, the surface of the wirebond wire 222 may be parallel or substantially parallel to the planar surface and may also be parallel or substantially parallel to a plane defined by support points of the rear of the chip assembly 200.

Provided that the wirebond wire 222 is longer than the shortest connection between the contact points and also bends after flat-pressing, the wire thickness, wire length, bending direction of the wire 222 and thickness of the chip contact 108 can be adjusted in such a way as to ensure that if bending takes place in the direction of the cavity 114, the wirebond wire 222 has a distance H2 from the chip substrate 104 that is non-zero, so that a short circuit can be avoided. For example, the thickness of the chip contact 108 can be 20 μm, and the wire thickness can be 17.5 μm.

FIGS. 3A and 3B each show schematic detailed views of chip assemblies 200 according to various exemplary embodiments.

FIG. 3A shows an overall representation and an enlarged representation of a central region of a chip assembly 200 according to various exemplary embodiments, with a plan view of the chip 100 and a part of the conductor track arrangement 102. FIG. 3A also shows an enlarged view of one of the regions with the wirebond wire 222. FIG. 3B is a schematic partial cross-sectional view along line B-B from FIG. 3A. The exemplary embodiment from FIG. 3A and FIG. 3B may be similar or identical to the exemplary embodiment described in relation to FIG. 2A to 2E.

The carrier 120 may comprise, for example, the (e.g., polymer) carrier strip 332, a rear metallization 334 and a rear substrate 336 (for example also a polymer) attached by means of a wirebond wire 338.

FIG. 4A to 4C illustrate the method for forming a chip assembly 200 according to various exemplary embodiments, in particular the flat-pressing process, which has already been described above in relation to FIGS. 2D and 2E.

In FIG. 4A, the wirebond wire 222 is arranged at two points, each between two contacts to be connected, namely each between a chip contact 108 and an associated carrier contact 116 (e.g., between 108, C-LA and 116, LA and between 108, C-LB and 116, LB).

FIG. 4B illustrates the reshaping process in which, by means of a punch 440 (or, if the flat-pressing is not carried out as cold forming but with an additional supply of heat and/or optionally ultrasonic energy, of a thermode) a force F (and optionally heat corresponding to a temperature T and/or ultrasonic energy) are transferred to the chip assembly 200 in order to shape (e.g., by flat-pressing) the wirebond wire 222 in at least one subregion.

Reshaping/flat-pressing may be continued until the target thickness H1 of the at least one flat-pressed subregion 222T1, 222T2 is reached, for example, a thickness not exceeding 10 μm, for example, not exceeding 5 μm.

FIG. 4C shows the generated chip assembly 200 with the wirebond wire 222 flat-pressed at two ends (each of the first subregion 222T1 and the second subregion 222T2).

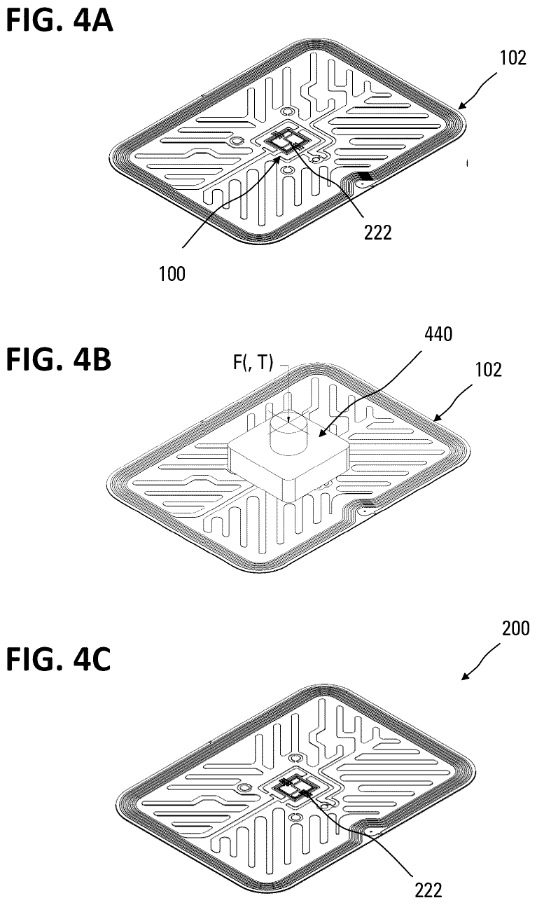

FIG. 5 shows schematic detailed views of chip assemblies 200 according to various exemplary embodiments, which differ in particular with regard to the number and arrangement of the wirebond wires 222.

Apart from this, the chip assemblies 200 of FIG. 5 to be formed in a similar or identical way to the chip assemblies 200 described above.

In the chip assembly 200 in the top illustration of FIG. 5, three wirebond wires 222 are laid in each case between the carrier contact LA/LB and the associated chip contact 108 via the shortest path, wherein the wirebond wires 222 each span one edge of the chip 100 and the two edges are opposite each other.

In the chip assembly 200 in the middle illustration of FIG. 5, three wirebond wires 222 are laid in each case between the carrier contact LA/LB and the associated chip contact 108 with an S-shaped bend, wherein the wirebond wires 222 each span one edge of the chip 100 and the two edges are opposite each other.

In the chip assembly 200 in the top representation of the FIG. 5, two groups of three wirebond wires 222 each are laid via the shortest path between the carrier contact LA/LB and the associated chip contact 108, wherein the wirebond wires 222 each span two edges of the chip 100, so that in total all four chip edges are spanned by wirebond wires 222.

Thus, the robustness of the chip assembly 200 can be increased because the probability that all of the wirebond wires 222 extending in two different directions, which connect one of the chip contacts 108 to the associated carrier contact LA/LB, might break, for example, by bending or twisting the chip assembly 200, is lower than if all connecting wirebond wires 222 are laid in the same direction.

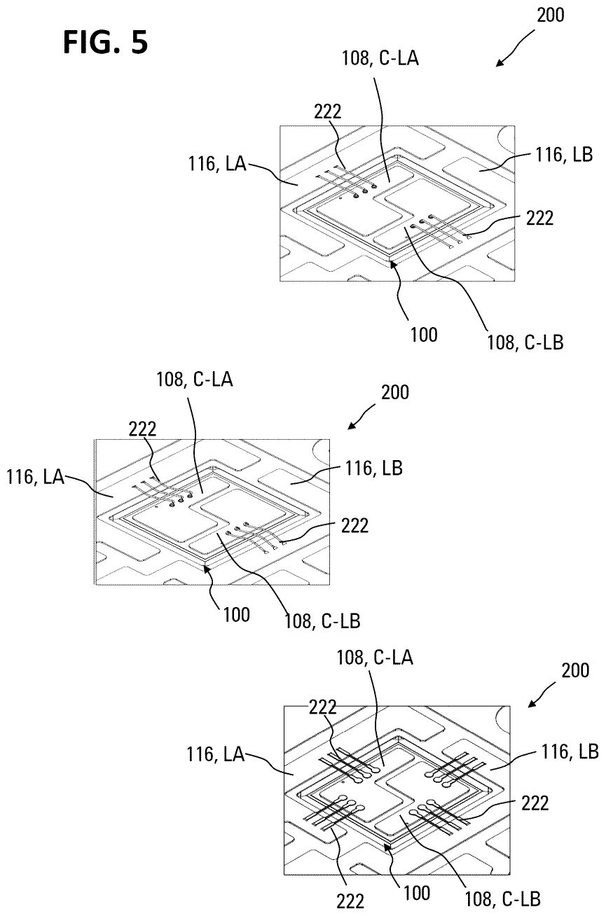

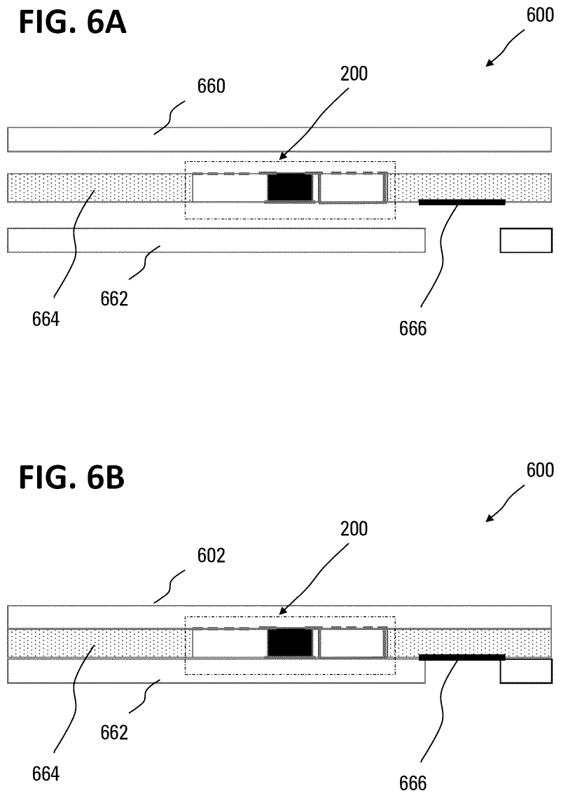

FIG. 6A shows an exploded drawing of a document structure 600 according to various exemplary embodiments, and FIG. 6B shows a schematic representation of the document structure 600 of FIG. 6A.

As already indicated above, the chip assembly 200 may be provided for being introduced into a very thin document structure 600.

The chip assembly 200 may be arranged, for example laminated, between a first document layer 660 and a second document layer 662, for example. For example, a material of the first document layer 660 and/or the second document layer 662 may comprise paper (which is frequently used), and/or other materials such as linens, plastic/polymers, or mixtures or combinations of these and possibly other materials.

In various examples, the chip assembly 200 may be arranged in a cavity of a carrier layer 664.

On the carrier layer 664, in various exemplary embodiments a security feature 666 may be additionally arranged. If the security feature 666 is provided for optical examination, the document layer 662 above it (here the second) can be provided with a viewing opening.

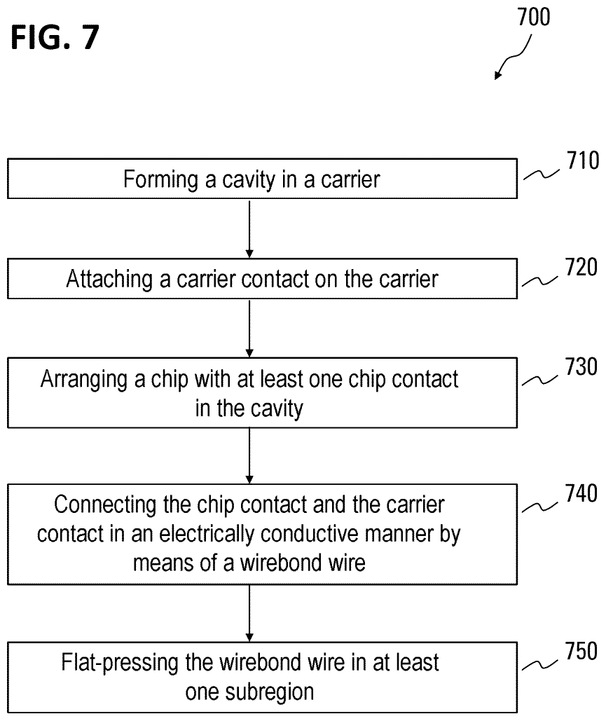

FIG. 7 shows a flowchart 700 of a method for forming a chip assembly according to various exemplary embodiments.

The method comprises forming a cavity in a carrier (710), applying at least one carrier contact to the carrier (720), arranging a chip having at least one chip contact in the cavity (730), connecting the at least one chip contact and the at least one carrier contact in an electrically conductive manner by means of a wirebond wire (740), and flat-pressing the wirebond wire in at least one subregion (750).

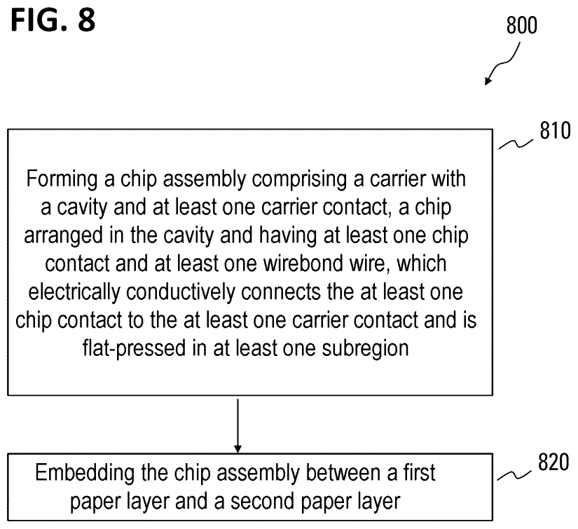

FIG. 8 shows a flowchart 800 of a method for forming a document structure according to various exemplary embodiments.

The method comprises forming a chip assembly according to one of the exemplary embodiments (810), for example, as described in connection with FIG. 7 and/or with FIG. 2A to 2E, and embedding the chip assembly between a first document layer and a second document layer (820).

In the following text, a summary of some exemplary embodiments is given.

Exemplary embodiment 1 is a chip assembly which comprises a carrier having a cavity and at least one carrier contact, a chip arranged in the cavity and having at least one chip contact, and at least one wirebond wire which electrically conductively connects the at least one chip contact to the at least one carrier contact, wherein the wirebond wire is flat-pressed in at least one subregion.

Exemplary embodiment 2 is a chip assembly according to exemplary embodiment 1, wherein the wirebond wire has a round or polygonal cross-section outside the at least one subregion.

Exemplary embodiment 3 is a chip assembly according to exemplary embodiment 1 or 2, wherein the wirebond wire is flatter in the at least one partial region than in another region of the wirebond wire.

Exemplary embodiment 4 is a chip assembly according to any of exemplary embodiments 1 to 3, wherein the at least one flat-pressed subregion has a first subregion, which in a plan view of the chip assembly lies within a surface region of the chip contact, and/or a second subregion, which in plan view lies within a surface region of the carrier contact.

Exemplary embodiment 5 is a chip assembly according to any of the exemplary embodiments 1 to 4, wherein the wirebond wire has a planar surface in the at least one subregion.

Exemplary embodiment 6 is a chip assembly according to any of exemplary embodiments 1 to 5, wherein when the chip assembly rests on a horizontal surface with a chip facing away from the surface, the planar surface of the wirebond wire is substantially parallel to the horizontal surface.

Exemplary embodiment 7 is a chip assembly according to any of exemplary embodiments 1 to 6, which further comprises a conductor track, for example an antenna, applied to one surface of the carrier, the carrier contact being electrically conductively connected to the conductor track, for example the antenna.

Exemplary embodiment 8 is a chip assembly according to any of the exemplary embodiments 1 to 7, wherein the chip has a plurality of edges which form a polygon (typically a rectangle, for example a square), wherein a single chip contact of the at least one chip contact extends along at least two edges.

Exemplary embodiment 9 is a chip assembly according to exemplary embodiment 8, wherein the wirebond wire contacts the individual chip contact over at least one of the at least two edges.

Exemplary embodiment 10 is a chip assembly according to any of the exemplary embodiments 1 to 9, wherein the wirebond wire is flat-pressed by means of pressure and/or heat and/or ultrasonic energy.

Exemplary embodiment 11 is a chip assembly according to any of the exemplary embodiments 1 to 10, wherein the wirebond wire has a maximum thickness of 10 μm, optionally a maximum of 5 μm, in at least one subregion.

Exemplary embodiment 11 is a chip assembly according to any of the exemplary embodiments 1 to 10, wherein the at least one chip contact is L-shaped.

Exemplary embodiment 12 is a chip assembly according to any of the exemplary embodiments 1 to 11, wherein the chip assembly has a maximum thickness of 80 μm.

Exemplary embodiment 13 is a chip assembly according to any of the exemplary embodiments 1 to 12, wherein the chip is a security chip.

Exemplary embodiment 14 is a document structure comprising a first document layer, a second document layer and a chip assembly according to any of the exemplary embodiments 1 to 13 between the first document layer and the second document layer.

Exemplary embodiment 15 is a method for forming a chip assembly, wherein the method comprises forming a cavity in a carrier, attaching at least one carrier contact to the carrier, arranging a chip having at least one chip contact in the cavity, connecting the at least one chip contact and the at least one carrier contact in an electrically conductive manner by means of a wirebond wire, and flat-pressing the wirebond wire in at least one subregion.

Exemplary embodiment 16 is a method according to exemplary embodiment 15, wherein the flat-pressing comprises cold-forming the wirebond wire.

Exemplary embodiment 17 is a method according to exemplary embodiment 15 or 16, wherein when the chip assembly rests on a horizontal surface with a chip facing away from the surface, the planar surface of the wirebond wire is substantially parallel to the horizontal surface.

Exemplary embodiment 18 is a method according to exemplary embodiment 15, wherein during the flat-pressing, heat and/or ultrasonic energy is supplied in addition to the force applied.

Exemplary embodiment 19 is a method according to any of the exemplary embodiments 15 to 18, wherein the wirebond wire has a maximum thickness of 10 μm, optionally a maximum of 5 μm, in at least one subregion.

Exemplary embodiment 20 is a method according to any of the exemplary embodiments 15 to 19, wherein the chip has a plurality of edges which form a polygon (typically a rectangle, for example a square), wherein a single chip contact of the at least one chip contact extends along at least two edges.

Exemplary embodiment 21 is a method according to exemplary embodiment 20, wherein the wirebond wire contacts the individual chip contact over at least one of the at least two edges.

Exemplary embodiment 22 is a method according to any of the exemplary embodiments 15 to 21, wherein the at least one chip contact is L-shaped.

Exemplary embodiment 23 is a method according to any of the exemplary embodiments 15 to 22, wherein the chip assembly has a maximum thickness of 80 μm.

Exemplary embodiment 24 is a method according to any of the exemplary embodiments 15 to 23, wherein the chip is a security chip.

Exemplary embodiment 25 is a method for forming a document structure, which comprises forming a chip assembly according to any of the embodiments 15 to 24 and embedding the chip assembly between a first document layer and a second document layer.

Exemplary embodiment 26 is a method according to exemplary embodiment 25, wherein the embedding comprises a lamination.

Additional advantageous designs of the device are obtained from the description of the method and vice versa.

1. A chip assembly, comprising:
a carrier with a cavity and at least one carrier contact;
a chip arranged in the cavity and having at least one chip contact; and
at least one wirebond wire which electrically conductively connects the at least one chip contact to the at least one carrier contact,
wherein the wirebond wire is flat-pressed in at least one subregion.

2. The chip assembly as claimed in claim 1,
wherein the wirebond wire has a round or polygonal cross-section outside the at least one subregion.

3. The chip assembly as claimed in claim 1,
wherein the wirebond wire is flatter in the at least one subregion than in another region of the wirebond wire.

4. The chip assembly as claimed in claim 1,
wherein the at least one flat-pressed subregion has a first subregion, which in a plan view of the chip assembly lies within a surface region of the chip contact, and/or a second subregion, which in plan view lies within a surface region of the carrier contact.

5. The chip assembly as claimed in claim 1,
wherein the wirebond wire has a planar surface in the at least one subregion.

6. The chip assembly as claimed in claim 1, further comprising:
an antenna mounted on a surface of the carrier,
wherein the carrier contact is electrically conductively connected to the antenna.

7. The chip assembly as claimed in claim 1,
wherein when the chip assembly rests on a horizontal surface with a chip facing away from the surface, the planar surface of the wirebond wire is substantially parallel to the horizontal surface.

8. The chip assembly as claimed in claim 1,
wherein the chip has a plurality of edges forming a polygon, and
wherein a single chip contact of the at least one chip contact extends along at least two edges.

9. The chip assembly as claimed in claim 8,
wherein the wirebond wire contacts the single chip contact across at least one of the at least two edges.

10. The chip assembly as claimed in claim 1,
wherein the at least one chip contact is L-shaped.

11. The chip assembly as claimed in claim 1,
wherein the chip assembly has a maximum thickness (H3) of 80 μm.

12. The chip assembly as claimed in claim 1,
wherein the chip is a security chip.

13. A document structure, comprising:
a first document layer;
a second document layer; and
a chip assembly as claimed in claim 1 between the first document layer and the second document layer.

14. A method for forming a chip assembly, the method comprising:
forming a cavity in a carrier;
applying a carrier contact to the carrier;
arranging a chip having at least one chip contact in the cavity;
electrically conductively connecting the chip contact and the carrier contact using a wirebond wire; and
flat-pressing the wirebond wire in at least one subregion.

15. The method as claimed in claim 14,
wherein the flat-pressing comprises cold forming the wirebond wire.

16. The method as claimed in claim 14,
wherein when the chip assembly rests on a horizontal surface with a chip facing away from the surface, the planar surface of the wirebond wire is substantially parallel to the horizontal surface.

17. The method as claimed in claim 13, further comprising:
during the flat-pressing, supplying heat and/or ultrasonic energy in addition to the force applied.

18. A method for forming a document structure, comprising:
forming a chip assembly as claimed in claim 13; and
embedding the chip assembly between a first document layer and a second document layer.

19. The method as claimed in claim 18,
wherein the embedding comprises a lamination.
